(19) United States
(12) Patent Application Publication
(10) Pub. No.: US 2016/0133808 A1
(43) Pub. Date: May 12, 2016

(54) METHOD OF PRODUCING AN OPTOELECTRONIC COMPONENT

(71) Applicant: OSRAM OPTO SEMICONDUCTORS GMBH, Regensburg (DE)

(72) Inventors: Martin Brandl, Kelheim (DE); Tobias Gebuhr, Regensburg (DE)

(21) Appl. No.: 14/900,699

(22) PCT Filed: Jun. 25, 2014
(86) PCT No.: PCT/EP2014/063379

§ 371 Date: Dec. 22, 2015

(30) Foreign Application Priority Data
Jun. 27, 2013 (DE) 10 2013 212 393.0

(51) Int. Cl. H01L 33/62; B29C 45/14; B29C 45/02; H01L 33/54; B29C 45/00

(52) U.S. Cl. CPC H01L 33/62; H01L 33/54; B29C 45/0055; B29C 45/02; B29C 45/14655; H01L 2933/005; H01L 2933/0066; B29K 2063/00

(57) ABSTRACT

A method of manufacturing an optoelectronic component includes providing a leadframe, wherein the leadframe has a first leadframe section and a second leadframe section, and the first leadframe section and the second leadframe section are physically separate from one another; embedding the leadframe into a plastic material by a molding process to form a casing body, wherein the first leadframe section and the second leadframe section are embedded into the plastic material at a physical interval; and reshaping of the plastic material to at least partially close a gap between the plastic material and the leadframe, wherein the plastic material is reshaped in a region arranged between the first leadframe section and the second leadframe section.

### TECHNICAL FIELD

This disclosure relates to a method of manufacturing an optoelectronic component.

### BACKGROUND

It is known to design optoelectronic components having casings that have a leadframe embedded into a plastic material by a transfer molding process or an injection molding process. A cavity in a plastic body—formed from the plastic material—of the casing of such optoelectronic components can be filled with a sealing material. However, embedding the leadframe into the plastic body can result in formation of gaps between the leadframe and the plastic material of the plastic body. Through these gaps, sealing material introduced into the cavity can advance to a rear of the casing body and contaminate solder contact pads at that location, for example.

It could therefore be helpful to provide a method of manufacturing an optoelectronic component.

### SUMMARY

We provide a method of manufacturing an optoelectronic component including providing a leadframe; embedding the leadframe into a plastic material by a molding process to form a casing body; and reshaping of the plastic material to at least partially close a gap between the plastic material and the leadframe.

We also provide a method of manufacturing an optoelectronic component including providing a leadframe, wherein the leadframe has a first leadframe section and a second leadframe section, and the first leadframe section and the second leadframe section are physically separate from one another; embedding the leadframe into a plastic material by a molding process to form a casing body, wherein the first leadframe section and the second leadframe section are embedded into the plastic material at a physical interval; and reshaping of the plastic material to at least partially close a gap between the plastic material and the leadframe, wherein the plastic material is reshaped in a region arranged between the first leadframe section and the second leadframe section.

### BRIEF DESCRIPTION OF THE DRAWINGS

FIG. 1 shows a section through a portion of a casing body of an optoelectronic component.

FIG. 2 shows a section through the casing body in a machined condition that is subsequent in time to the representation in FIG. 1.

FIG. 3 shows a section through the casing body in a machine condition that is subsequent in time to the representation in FIG. 2.

FIG. 4 shows a section through the casing body with an optoelectronic semiconductor chip arranged in a cavity.

FIG. 5 shows a section through an optoelectronic component.

### LIST OF REFERENCE SYMBOLS

100 Optoelectronic component
200 Casing body
201 top
202 Bottom
210 Cavity
220 Gap
225 Sealed gap
230 Sealing material
300 Plastic body
301 Top
302 Bottom
310 Plastic material
320 Intermediate region
330 Notch
400 Leadframe
410 First leadframe section
411 Chip holding area
412 First solder contact pad
420 Second leadframe section
421 Bonding pad
422 Second solder contact pad
500 Optoelectronic semiconductor chip
501 Top
502 Bottom
510 First electrical contact pad
520 Second electrical contact pad
530 Bonding wire
540 Connecting means
600 Plunger
610 Direction

### DETAILED DESCRIPTION

A method of manufacturing an optoelectronic component comprises steps to provide a leadframe, embed the leadframe into a plastic material by a molding process to form a casing body, and reshape the plastic material to at least partially close a gap between the plastic material and the leadframe. Advantageously, a cavity in a casing body of an optoelectronic component manufactured using the method can be filled with a sealing material without the sealing material then being able to get through gaps between the plastic material and the leadframe. This prevents undesirable contamination of solder contact pads and other portions of the optoelectronic component. This advantageously saves method steps of identifying any undesirable contamination and removing any undesirable contamination. As a result, the method can advantageously be performed particularly simply and inexpensively. At the same time, the optoelectronic component that can be obtained using the method advantageously has a particularly high level of reliability owing to prevention of undesirable contamination.

Reshaping may be effected after the molding process before the plastic material is completely set. Advantageously, this means that no renewed heating of the plastic material is required to put the plastic material into a deformable state. As a result, the method can be performed particularly simply, quickly and inexpensively.

Reshaping may be effected after the casing body is deflashed. Advantageously, deflashing the casing body is accompanied by heating of the plastic material that puts the plastic material into a deformable state. This means that after the casing body is deflashed it is possible to reshape the plastic material without this requiring further preparatory steps. As a result, the method can advantageously be performed particularly simply, quickly and inexpensively.

Reshaping may be effected by exerting a mechanical force on the plastic material. Advantageously, this means that reshaping can be performed particularly simply and reproducibly.

The force may be exerted on the plastic material by a plunger. Advantageously, this allows the force to be exerted on the plastic material particularly precisely and reproducibly.

The leadframe may be embedded into the plastic material in a mold tool. In this case, the plunger forms part of the mold tool. Advantageously, embedding the leadframe by the molding process and reshaping the plastic material can then take place in the same tool as a result of which the method can be performed particularly simply, quickly and inexpensively.

The molding process may be a transfer molding or injection molding process. Advantageously, the transfer molding and injection molding processes allow inexpensive and accurate embedding of the leadframe into the plastic material.

The leadframe may be provided to have a first leadframe section and a second leadframe section. In this case, the first leadframe section and the second leadframe section are physically separate from one another. Furthermore, the first leadframe section and the second leadframe section are embedded into the plastic material at a physical interval. Advantageously, the leadframe sections of the leadframe of the optoelectronic component that can be obtained using this method can be used to make electrical contact with an optoelectronic semiconductor chip of the optoelectronic component.

The plastic material may be reshaped in a region arranged between the first leadframe section and the second leadframe section. Advantageously, this means that the reshaping takes place in a region of the casing body formed from the plastic material and the leadframe sections and in which a risk of undesirable gaps forming is particularly high.

The first leadframe section may be provided to have a first solder contact pad. In this case, the second leadframe section is provided to have a second solder contact pad. The first leadframe section and the second leadframe section are embedded into the plastic material such that the first solder contact pad and the second solder contact pad remain at least partially uncovered by the plastic material. In this case, the plastic material is reshaped by exerting a mechanical force on a region of the plastic material arranged between the first solder contact pad and the second solder contact pad. Advantageously, during reshaping of the plastic material, this allows gaps between the plastic material and the leadframe sections to be closed in the region between the two leadframe sections. This advantageously prevents a subsequent process step from involving sealing material used to fill a cavity of the casing body advancing along any gaps between the leadframe sections and the plastic material to the solder contact pads of the leadframe sections of the optoelectronic component that can be obtained using the method and being able to contaminate the solder contact pads.

The first leadframe section may be provided to have a chip holding area. Furthermore, the first leadframe section is embedded into the plastic material such that the chip holding area remains at least partially uncovered by the plastic material. Advantageously, the chip holding area of the first leadframe section of the optoelectronic component that can be obtained by this method can be used to electrically connect an optoelectronic semiconductor chip of the optoelectronic component.

The method may have a further step of arrangement of an optoelectronic semiconductor chip on the chip holding area. Advantageously, the chip holding area can be used to electrically connect the optoelectronic semiconductor chip.

The casing body may be produced with a cavity adjoining the chip holding area. In this case, the method comprises a further step of arranging a sealing material in the cavity. Advantageously, an optoelectronic semiconductor chip arranged in the cavity in the casing body of the optoelectronic component is protected from damage by external mechanical actions by the sealing material arranged in the cavity. Furthermore, the sealing material introduced into the cavity can also be used to convert electromagnetic radiation emitted by an optoelectronic semiconductor chip of the optoelectronic component that can be obtained using the method. Advantageously, the method step of reshaping the plastic material, which precedes the arrangement of the sealing material, ensures that the sealing material arranged in the cavity cannot get through gaps between the plastic material and the leadframe. This advantageously prevents inadvertent damage to the optoelectronic component while the sealing material is being arranged in the cavity.

The second leadframe section may be provided to have a bonding pad. In this case, the second leadframe section is embedded into the plastic material such that the bonding pad remains at least partially uncovered by the plastic material. Advantageously, the bonding pad of the second leadframe section can then be electrically conductively connected to an electrical contact of an optoelectronic semiconductor chip of the optoelectronic component that can be obtained using the method, as a result of which the second leadframe section can be used to make electrical contact with the optoelectronic semiconductor chip.

The method may comprise a further step of arranging a bonding wire between the optoelectronic semiconductor chip and the bonding pad. Advantageously, this sets up an electrically conductive connection between the optoelectronic semiconductor chip and the bonding pad. As a result, the second leadframe section can be used to make electrical contact with the optoelectronic semiconductor chip of the optoelectronic component that can be obtained by the method.

The properties, features and advantages described above and also the manner in which they are achieved will become clearer and more distinctly comprehensible in connection with the description of the examples that follows, the examples being explained in more detail in connection with the drawings.

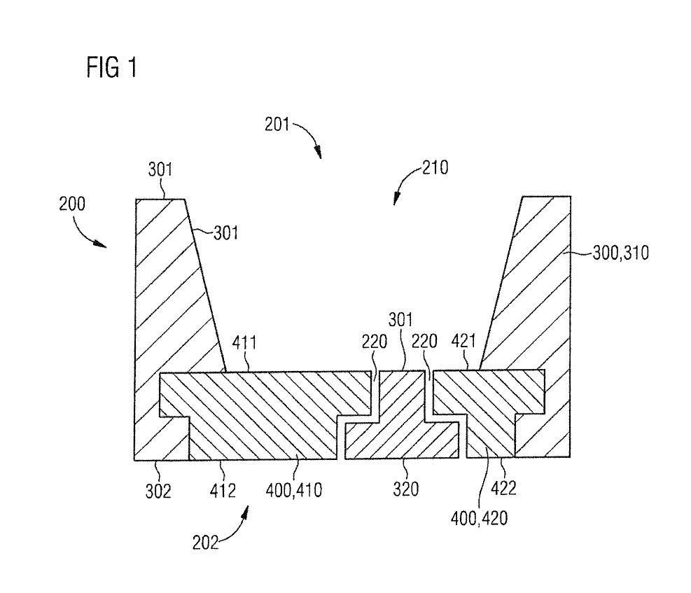

FIG. 1 shows a schematic sectional representation of a casing body 200 in an unfinished machined condition during the manufacture thereof. By way of example, the casing body 200 can form part of a casing of an optoelectronic component. By way of example, the casing body 200 can be used as part of a casing of a light-emitting-diode component. The casing of the optoelectronic component can also be referred to as a package.

The casing body 200 comprises a plastic body 300 and a leadframe 400 embedded in the plastic body 300. The plastic body 300 has an electrically insulating plastic material 310. By way of example, the plastic material 310 may be an epoxy resin, a thermoplastic or a thermoset. The leadframe 400 has an electrically conductive material. By way of example, the leadframe 400 can have copper or a copper alloy. The leadframe 400 may furthermore have a solderable coating on its outer faces.

The casing body 200 has a top 201 and a bottom 202 opposite the top 201. At the top 201 of the casing body 200, a cavity 210 is formed. The cavity 210 forms a depression at the top 201 of the casing body 200, which depression is open toward the top 201 of the casing body 200. In the lateral direction at right angles to the sectional representation in FIG. 1, the cavity 210 can have a rectangular or disk-shaped cross-sectional area, for example. In the vertical direction, the cavity 210 may be in cylindrical form or, as shown in FIG. 1, widen conically. The cavity 210 then thus has a cylindrical or truncated-cone-shaped or truncated-pyramid-shaped volume. The form of the cavity 210 may alternatively have a more complex geometry.

The plastic body 300 of the casing body 200 has a top 301 that forms part of the top 201 of the casing body 200. Furthermore, the plastic body 300 has a bottom 302 that forms part of the bottom 202 of the casing body 200. The plastic body 300 forms the walls of the casing body 200 that delimit the cavity 210 in the casing body 200 at the sides.

The leadframe 400 comprises a first leadframe section 410 and a second leadframe section 420. The first leadframe section 410 and the second leadframe section 420 of the lead-frame 400 are physically separate from one another and electrically insulated from one another. The first leadframe section 410 and the second leadframe section 420 of the leadframe 400 are embedded in the plastic material 310 of the plastic body 300 at an interval from one another.

The first leadframe section 410 of the leadframe 400 has a chip holding area 411 and a first solder contact pad 412 opposite the chip holding area 411. The second leadframe section 420 of the leadframe 400 has a bonding pad 421 and a second solder contact pad 422 opposite the bonding pad 421. The chip holding area 411 and the first solder contact pad 412 of the first leadframe section 410 and also the bonding pad 421 and the second solder contact pad 422 of the second leadframe section 420 are each at least partially not covered by the plastic material 310 of the plastic body 300. In the example shown in FIG. 1, the chip holding area 411 of the first leadframe section 410 and the bonding pad 421 of the second leadframe section 420 are partially covered by the plastic material 310 of the plastic body 300 and otherwise uncovered. The first solder contact pad 412 of the first leadframe section 410 and the second solder contact pad 422 of the second leadframe section 420 are completely uncovered by the plastic material 310 of the plastic body 300.

Those sections of the chip holding area 411 of the first leadframe section 410 and the bonding pad 421 of the second leadframe section 420 uncovered by the plastic material 310 of the plastic body 300 form part of the top 201 of the casing body 200 in the bottom region of the cavity 210 of the casing body 200. The first solder contact pad 412 of the first leadframe section 410 and the second solder contact pad 422 of the second leadframe section 420 terminate flush with the bottom 302 of the plastic body 300 and form parts of the bottom 202 of the casing body 200.

The leadframe sections 410, 420 of the leadframe 400 have been embedded into the plastic material 310 of the plastic body 300 by a molding process. In this case, the leadframe sections 410, 420 of the leadframe 400 have been embedded into the plastic material 310 at the same time as the plastic body 300 was produced from the plastic material 310. By way of example, the molding process may be a transfer molding process or an injection molding process. The molding process may have been performed in a mold tool.

Gaps 220 are formed in the casing body 200 formed by the plastic body 300 and the embedded leadframe sections 410, 420 of the leadframe 400 between the plastic material 310 of the plastic body 300 and the leadframe sections 410, 420 of the leadframe 400. The gaps 220 are shown only schematically in FIG. 1. The gaps 220 extend along the boundaries between the plastic material 310 of the plastic body 300 and the leadframe sections 410, 420 between the bottom 202 of the casing body 200 and the cavity 210 at the top 201 of the casing body 200.

The gaps 220 between the leadframe sections 410, 420 and the plastic material 310 of the plastic body 300 do not have to be formed in all cases, and do not have to be formed in all regions, between the leadframe sections 410, 420 and the plastic material 310 of the plastic body 300. However, there is always a certain probability during the manufacture of the casing body 200 that at least some gaps 220 will be formed between the bottom 202 and the top 201 in the region of the cavity 210 in the casing body 200.

Formation of the gaps 220 can be caused by slight adhesion between the plastic material 310 of the plastic body 300 and the surfaces of the leadframe sections 410, 420 of the leadframe 400. The gaps 220 can also result from mechanical loads acting on the casing body 200 during a demolding process after the molding process for forming the plastic body 300. Even during deflashing (deflash process) that follows the molding process, gaps 220 can be formed between the leadframe sections 410, 420 of the leadframe 400 and the plastic material 310 of the plastic body 300.

If a later machining step involves a sealing material being used to fill the cavity 210 in the casing body 200, some of the sealing material can flow through the gaps 220 to the bottom 202 of the casing body 200 and advance as far as the solder contact pads 412, 422 of the leadframe sections 410, 420. If the sealing material wets the solder contact pads 412, 422 of the leadframe sections 410, 420 partly or completely as it does so, this can hamper or completely prevent wetting of the solder contact pads 412, 422 with solder and, as a result, setup of a solder connection to the casing body 200. In this case, the casing body 200 and an optoelectronic component produced from the casing body 200 become unusable.

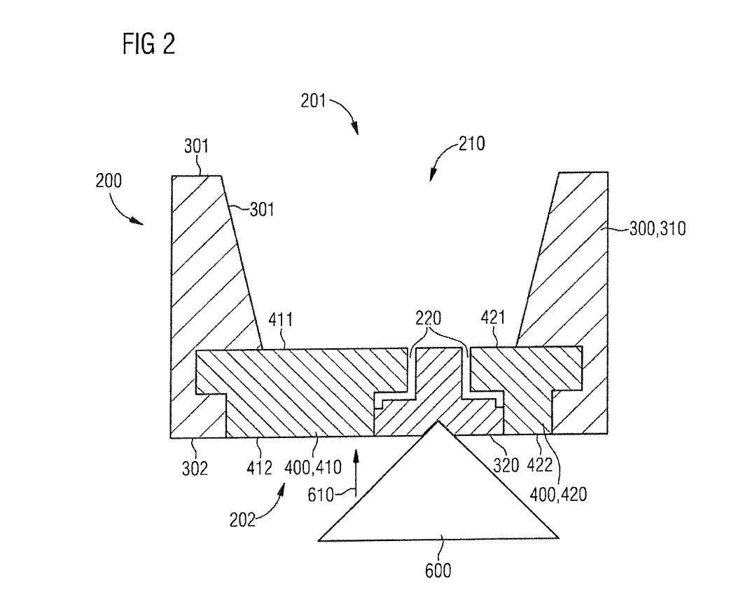

For these reasons, it is necessary to seal the gaps 220 between the leadframe sections 410, 420 of the leadframe 400 and the plastic material 310 of the plastic body 300. FIG. 2 shows a schematic representation of a corresponding machining step for the casing body 200 subsequent in time to the machined condition shown in FIG. 1 for the casing body 200.

The plastic material 310 of the plastic body 300 is reshaped to seal the gaps 220. The plastic material 310 of the plastic body 300 is reshaped by exerting a mechanical force on the plastic material 310. The mechanical force is exerted on the plastic material 310 of the plastic body 300 by a plunger 600, which is shown only schematically in FIG. 2.

The mechanical force exerted on the plastic material 310 of the plastic body 300 reshapes the plastic material 310 of the plastic body 300 such that the gaps 220 between the leadframe sections 410, 420 and the plastic material 310 of the plastic body 300 are at least partially closed.

Preferably, the plastic material 310 is reshaped at a time at which the plastic material 310 is heated and plastically deformable. By way of example, and preferably, the plastic material 310 can be reshaped immediately after the plastic body 300 is produced by the molding process and before the plastic material 310 has completely cooled and solidified. The final setting of the plastic material 310 can also take place in a furnace process.

Alternatively or additionally, the plastic material 310 can also be reshaped after the casing body 200 has been deflashed. In this case, deflashing the casing body 200 can be accompanied by heating and softening the plastic material 310 of the plastic body 300. The plastic material 310 is then reshaped preferably before the plastic material 310 cools again and sets. Alternatively or additionally, the plastic material 310 of the plastic body 300 can also be reshaped at any other time during the machining of the casing body 200, however. In this case, the reshaping of the plastic material 310 of the plastic body 300 can be preceded by heating of the plastic material 310 of the plastic body 300 to soften the plastic material 310 and render it plastically deformable.

If the plastic material 310 of the plastic body 300 is reshaped immediately after the molding process of producing the plastic body 300, the plunger 600 may be in the form of part of a mold tool used during the molding process. In that case, the plunger 600 may be arranged to move in an interior of a hollow form in the mold tool, for example. The plastic material 310 of the plastic body 300 is then reshaped still within the mold tool used for the molding process, as a result of which particularly reliable closure of the gaps 220 can be achieved owing to the forming force exerted on the plastic body 300 by the mold tool.

The plastic material 310 of the plastic body 300 is reshaped by virtue of the plunger 600 exerting a mechanical force on the plastic material 310 of the plastic body 300. To this end, the plunger 600 is pushed against the plastic body 300 in a direction 610. By way of example, the plunger 600 can be pushed against the bottom 302 of the plastic body 300.

Particularly reliable sealing of the gaps 220 formed between the leadframe sections 410, 420 of the leadframe 400 and the plastic material 310 of the plastic body 300 can be achieved when the plunger 600 is pressed against the bottom 302 of the plastic body 300 in a region 320 of the plastic body 300 situated between the first solder contact pad 412 of the first leadframe section 410 and the second solder contact pad 422 of the second leadframe section 420. The direction 610 in which the plunger 600 is pushed against the plastic body 300 is oriented at right angles to the bottom 302 of the plastic body 300 in this case.

It is also possible to reshape the plastic material 310 of the plastic body 300 in a plurality of regions of the plastic body 300 to achieve particularly reliable sealing of the gaps 220. To this end, the plunger 600 or plurality of plungers can be used to exert a mechanical force on different regions of the plastic body 300. By way of example, a mechanical force can be exerted on a plurality of different regions of the bottom 302 of the plastic body 300. In this case, the force can be exerted on the different portions of the bottom 302 of the plastic body 300 at the same time or in succession.

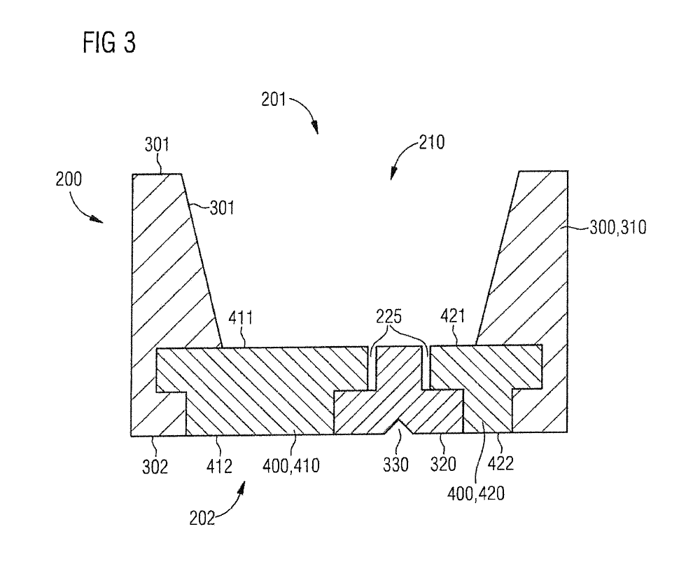

FIG. 3 shows a schematic sectional representation of the casing body 200 in a machined condition subsequent in time to the reshaping of the plastic material 310 of the plastic body 300. Reshaping the plastic material 310 of the plastic body 300 means that the gaps 220 between the leadframe sections 410, 420 of the leadframe 400 and the plastic material 310 of the plastic body 300 have been at least partially closed and now form at least partially sealed gaps 225. Preferably, the sealed gaps 225 are sealed to such an extent that there is no longer a continuous connection between the bottom 202 of the casing body 200 and the top 201 of the casing body 200 in the region of the cavity 210.

The plastic body 300 may have a notch 330 in the region in which a mechanical force has been exerted on the plastic material 310 of the plastic body 300 by the plunger 600. By way of example, the notch 330 may be arranged on the bottom 302 of the plastic body 300 in the intermediate region 320 of the plastic body 300 that is situated between the first solder contact pad 412 of the first leadframe section 410 and the second solder contact pad 422 of the second leadframe section 420. The plastic body 300 may also have a plurality of notches 330. Alternatively, it may be possible for the plastic material 310 of the plastic body 300 to be reshaped such that no visible notch 330 remains.

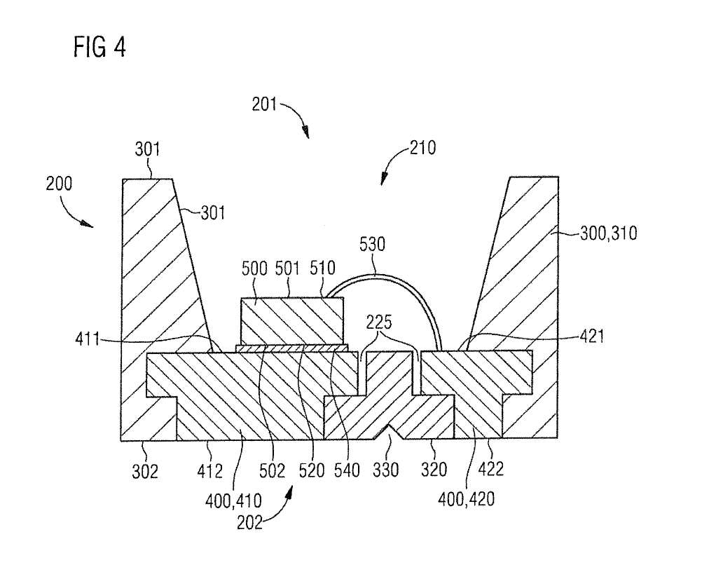

FIG. 4 shows a further schematic sectional representation of the casing body 200 in a machined state that is subsequent in time to the representation in FIG. 3. An optoelectronic semiconductor chip 500 has been arranged in the cavity 210 in the casing body 200. By way of example, the optoelectronic semiconductor chip 500 may be a light-emitting-diode chip (LED chip).

The optoelectronic semiconductor chip 500 has a top 501 and a bottom 502 opposite the top 501. Arranged on the top 501 of the optoelectronic semiconductor chip 500 there is a first electrical contact pad 510 of the optoelectronic semiconductor chip 500. Arranged on the bottom 502 of the optoelectronic semiconductor chip 500 there is a second electrical contact pad 520. An electrical voltage can be applied to the optoelectronic semiconductor chip 500 between the first electrical contact pad 510 and the second electrical contact pad 520 to prompt the optoelectronic semiconductor chip 500 to emit electromagnetic radiation, for example, to emit visible light. The electrical contact pads 510, 520 of the optoelectronic semiconductor chip 500 could also be arranged in a different manner than shown. By way of example, both electrical contact pads 510, 520 could be arranged on the top 501 or on the bottom 502 of the optoelectronic semiconductor chip 500.

The optoelectronic semiconductor chip 500 is arranged on the chip holding area 411 of the first leadframe section 410 in the bottom region of the cavity 210 in the casing body 200. The bottom 502 of the optoelectronic semiconductor chip 500 faces the chip holding area 411 of the first leadframe section 410 and is electrically connected thereto by a connecting means 540. As a result, there is an electrically conductive connection between the second electrical contact pad 520 of the optoelectronic semiconductor chip 500 arranged on the bottom 502 of the optoelectronic semiconductor chip 500 and the first leadframe section 410. By way of example, the connecting means 540 may be a solder or an electrically conductive adhesive.

The first electrical contact pad 510 arranged on the top 501 of the optoelectronic semiconductor chip 500 electrically conductively connects to the bonding pad 421 of the second leadframe section 420 by a bonding wire 530. As a result, there is an electrically conductive connection between the second electrical contact pad 520 of the optoelectronic semiconductor chip 500 and the second leadframe section 420 of the casing body 200. Hence, the optoelectronic semiconductor chip 500 can have electrical voltage applied to it via the first solder contact pad 412 and the second solder contact pad 422 of the casing body 200.

It is also possible to use an optoelectronic semiconductor chip in the form of a flip chip in which both electrical contact pads are arranged on the bottom. In this case, the optoelectronic semiconductor chip can be arranged on the chip holding area 411 of the first leadframe section 410 and the bonding pad 421 of the second leadframe section 420 such that the electrical contact pads of the optoelectronic semiconductor chip electrically conductively connect to the first leadframe section 410 and the second leadframe section 420. The bonding pad 421 of the second leadframe section 420 could then also be referred to as a second chip holding area.

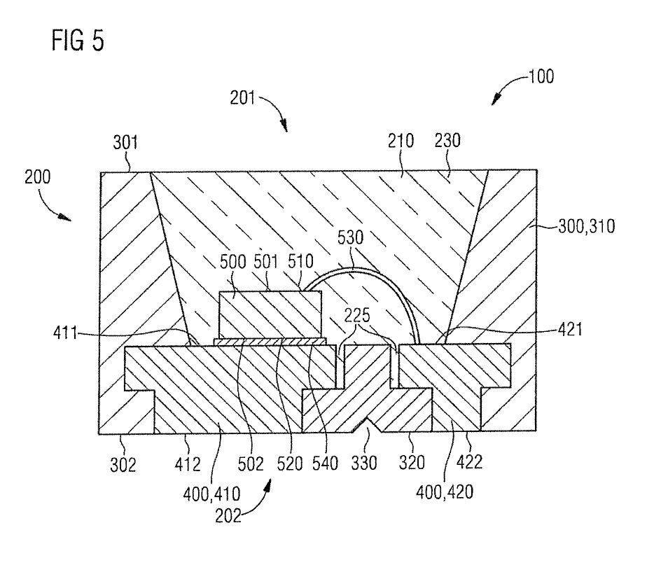

FIG. 5 shows a further schematic representation of the casing body 200 and of the optoelectronic semiconductor chip 500 arranged in the cavity 210 in the casing body 200 in a machined condition that is subsequent in time to the representation in FIG. 4. In the representation in FIG. 5, the casing body 200 and the optoelectronic semiconductor chip 500 form parts of an optoelectronic component 100 that has finished being processed. By way of example, the optoelectronic component 100 may be a light-emitting-diode component.

A sealing material 230 has been arranged in the cavity 210 in the casing body 200. In this case, the optoelectronic semiconductor chip 500 and the bonding wire 530 have been embedded into the sealing material 230. Preferably, the optoelectronic semiconductor chip 500 and the bonding wire 530 are completely surrounded by the sealing material 230. As a result, the optoelectronic semiconductor chip 500 and the bonding wire 530 are protected from damage by external mechanical actions by the sealing material 230. The sealing material 230 can completely fill the cavity 210 in the casing body 200. The sealing material 230 can alternatively only partially fill the cavity 210 in the casing body 200.

The sealing material 230 preferably has a material that is optically essentially transparent to electromagnetic radiation emitted by the optoelectronic semiconductor chip 500. By way of example, the sealing material 230 can have silicone. Furthermore, the sealing material 230 can have an embedded phosphor. In this case, the phosphor, as a wavelength-converting phosphor, can be used to convert a wavelength of electromagnetic radiation emitted by the optoelectronic semiconductor chip 500. In this case, the phosphor absorbs electromagnetic radiation emitted by the optoelectronic semiconductor chip 500, having a first wavelength and to emit electromagnetic radiation having a second, typically larger, wavelength. By way of example, the embedded phosphor of the sealing material 230 may be an organic phosphor or an inorganic phosphor. The phosphor may also have quantum dots.

No sealing material 230 has been able to get through the sealed gaps 225 from the cavity 210 to the bottom 202 of the casing body 200 during the introduction of the sealing material 230 into the cavity 210 in the casing body 200. This has prevented the sealing material 230 from contaminating the solder contact pads 412, 422 of the leadframe sections 410, 420 of the leadframe 400 of the casing body 200 on the bottom 202 of the casing body 200.

By way of example, the optoelectronic component 100 is suitable as an SMD component for surface mounting. In this case, the first solder contact pad 412 and the second solder contact pad 422 of the casing body 200 of the optoelectronic component 100 can be soldered and have electrically conductive contact made with it by reflow soldering, for example. Since the sealed gaps 225 mean that the solder contact pads 412, 422 of the casing body 200 of the optoelectronic component 100 are not contaminated with sealing material 230, adequate wetting of the solder contact pads 412, 422 of the casing body 200 of the optoelectronic component 100 with solder is ensured during soldering of the optoelectronic component 100.

The top 501 of the optoelectronic semiconductor chip 500 forms a radiation emission area. During operation of the optoelectronic component 100, electromagnetic radiation is emitted from the top 501 of the optoelectronic semiconductor chip 500 and can get through the sealing material 230 to the top 201 of the casing body 200 and can be radiated therefrom. In this case, the sealing material 230 arranged in the cavity 210 in the casing body 200 of the optoelectronic component 100 can prompt conversion of the wavelength of the electromagnetic radiation. The walls of the cavity 210 in the casing body 200 of the optoelectronic component 100 that are formed by the plastic material 310 of the plastic body 300 can be used as reflectors for the electromagnetic radiation emitted by the optoelectronic semiconductor chip 500.

Our methods have been illustrated and described in more detail on the basis of the preferred examples. Nevertheless, this disclosure is not restricted to the examples disclosed. Rather, other variations can be derived therefrom by those skilled in the art without departing from the scope of protection of the disclosure.

This application claims priority of DE 10 2013 212 393.0, the disclosure of which is incorporated herein by reference.

1-15. (canceled)

16. A method of manufacturing an optoelectronic component comprising:
providing a leadframe;
embedding the leadframe into a plastic material by a molding process to form a casing body; and
reshaping of the plastic material to at least partially close a gap between the plastic material and the leadframe.

17. The method as claimed in claim 16, wherein the reshaping is effected after the molding process before the plastic material is completely set.

18. The method as claimed in claim 16, wherein the reshaping is effected after the casing body is deflashed.

19. The method as claimed in claim 16, wherein the reshaping is effected by exerting a mechanical force on the plastic material.

20. The method as claimed in claim 19, wherein the force is exerted on the plastic material by a plunger.

21. The method as claimed in claim 20, wherein the leadframe is embedded into the plastic material in a mold tool, and the plunger forms part of the mold tool.

22. The method as claimed in claim 16, wherein the molding process is a transfer molding or injection molding process.

23. The method as claimed in claim 16,
wherein the leadframe has a first leadframe section and a second leadframe section,
the first leadframe section and the second leadframe section are physically separate from one another, and
the first leadframe section and the second leadframe section are embedded into the plastic material at a physical interval.

24. The method as claimed in claim 23, wherein the plastic material is reshaped in a region arranged between the first leadframe section and the second leadframe section.

25. The method as claimed in claim 19,
wherein the first leadframe section has a first solder contact pad and the second leadframe section has a second solder contact pad,
the first leadframe section and the second leadframe section are embedded into the plastic material such that the first solder contact pad and the second solder contact pad remain at least partially uncovered by the plastic material, and
the plastic material is reshaped by exerting a mechanical force on a region of the plastic material arranged between the first solder contact pad and the second solder contact pad.

26. The method as claimed in claim 25,
wherein the first leadframe section has a chip holding area, and
the first leadframe section is embedded into the plastic material such that the chip holding area remains at least partially uncovered by the plastic material.

27. The method as claimed in claim 26, further comprising arranging an optoelectronic semiconductor chip on the chip holding area.

28. The method as claimed in claim 26, further comprising arranging a sealing material in the cavity, wherein the casing body is produced with a cavity adjoining the chip holding area.

29. The method as claimed in claim 25,
wherein the second leadframe section has a bonding pad, and
the second leadframe section is embedded into the plastic material such that the bonding pad remains at least partially uncovered by the plastic material.

30. The method as claimed in claim 27, further comprising arranging a bonding wire between the optoelectronic semiconductor chip and the bonding pad.

31. A method of manufacturing an optoelectronic component comprising:
providing a leadframe, wherein the leadframe has a first leadframe section and a second leadframe section, and the first leadframe section and the second leadframe section are physically separate from one another;
embedding the leadframe into a plastic material by a molding process to form a casing body, wherein the first leadframe section and the second leadframe section are embedded into the plastic material at a physical interval; and
reshaping of the plastic material to at least partially close a gap between the plastic material and the leadframe, wherein the plastic material is reshaped in a region arranged between the first leadframe section and the second leadframe section.

32. The method as claimed in claim 29, further comprising arranging a bonding wire between the optoelectronic semiconductor chip and the bonding pad.

33. The method as claimed in claim 24,
wherein the first leadframe section has a first solder contact pad and the second leadframe section has a second solder contact pad,
the first leadframe section and the second leadframe section are embedded into the plastic material such that the first solder contact pad and the second solder contact pad remain at least partially uncovered by the plastic material, and
the plastic material is reshaped by exerting a mechanical force on a region of the plastic material arranged between the first solder contact pad and the second solder contact pad.
